(19) United States
(12) Patent Application Publication
(10) Pub. No.: US 2026/0333617 A1
(43) Pub. Date: Oct. 22, 2026

(54) INDUCTION HEATING COOKING DEVICE

(71) Applicant: SAMSUNG ELECTRONICS CO., LTD., Suwon-si (KR)

(72) Inventors: Myoungkeun KWON, Suwon-si (KR); Dongwoo SHIN, Suwon-si (KR); Kyounghwan KIM, Suwon-si (KR); Younghoon WOO, Suwon-si (KR); Heejin YOON, Suwon-si (KR)

(73) Assignee: SAMSUNG ELECTRONICS CO., LTD., Suwon-si (KR)

(21) Appl. No.: 19/712,826

(22) Filed: Jun. 18, 2026

Related U.S. Application Data
(63) Continuation of application No. PCT/KR2024/018203, filed on Nov. 19, 2024.

(30) Foreign Application Priority Data
Feb. 6, 2024 (KR) 10-2024-0018482

(51) Int. Cl. H05K 7/20; H05B 6/12

(52) U.S. Cl. CPC H05K 7/20154; H05B 6/1209; H05K 7/20145

(57) ABSTRACT

An induction heating cooking device comprising a plate to allow a cooking container to be placed thereon; a heating device configured to heat the cooking container by receiving a driving current from a printed circuit board; and a user interface to receive a user input for operating the heating device. In addition, the induction heating cooking device comprises: a heat dissipation member disposed below the user interface and provided to be able to exchange heat with the printed circuit board; and a cooling fan provided to generate an air flow to cool the heat dissipation member. In addition, the induction heating cooking device comprises a branch guide, including a first flow path and a second flow path, to guide a portion of the air flow generated by the cooling fan to the user interface, where the second flow path is disposed above and separated from the first flow path such that air to cool the heat dissipation member flows through the first flow path.

### CROSS-REFERENCE TO RELATED APPLICATION

This application is a continuation application, under 35 U.S.C. § 111(a), of international application No. PCT/KR2024/018203, filed Nov. 19, 2024, which claims priority under 35 U.S. C. § 119 to Korean Patent Application No. 10-2024-0018482, filed Feb. 6, 2024, the disclosures of which are incorporated herein by reference in their entireties.

### TECHNICAL FIELD

The present disclosure relates to an induction heating cooking device.

### BACKGROUND ART

An induction heating cooking device generates a high-frequency magnetic flux that passes through an object to be heated that is loaded on an upper plate by flowing a high-frequency current through a heating coil, and heats the object to be heated such as a frying pan or pot using electromagnetic induction. In the Induction Heating (IH), as the high-frequency magnetic flux passes through the object to be heated, it induces eddy currents in the object to be heated, and the object to be heated is heated by the heat generated by its own electrical resistance.

In the induction heating cooking device, when heating the object to be heated by induction, the heating coil generates heat due to a phenomenon known as the skin effect or proximity effect, which causes energy loss.

Regarding the operation of induction heating cooking devices, various smart technologies may be incorporated to enhance user convenience. For example, user interface devices, such as Light Emitting Diode (LED) or Liquid Crystal Display (LCD) panels, capable of controlling the operation of the heating coil and displaying other information, may be installed on one surface of the induction heating cooking device to improve usability.

### DISCLOSURE

### Technical Problem

The present disclosure is directed to providing an induction heating cooking device capable of cooling a user interface device.

Further, the present disclosure is directed to providing an induction heating cooking device including a structure configured to guide a portion of a cooling airflow flowing to a heat dissipation member to a user interface device.

Further, the present disclosure is directed to providing an induction heating cooking device including a structure configured not to impede heat exchange effect of a heat dissipation member when guiding a portion of a cooling airflow to a user interface device.

Additional aspects of the disclosure will be set forth in part in the description which follows and, in part, will be obvious from the description, or may be learned by practice of the disclosure.

### Technical Solution

One aspect of the present disclosure provides an induction heating cooking device including: a plate to allow a cooking container to be placed thereon; a heating device configured to heat the cooking container by receiving a driving current from a printed circuit board; and a user interface to receive a user input for operating the heating device. The induction heating cooking device includes: a heat dissipation member disposed below the user interface and configured to exchange heat with the printed circuit board; and a cooling fan configured to generate an airflow for cooling the heat dissipation member. The induction heating cooking device includes a branch guide, including a first flow path and a second flow path, to guide a portion of the airflow generated by the cooling fan to the user interface. The second flow path is disposed above and separated from the first flow path such that air to cool the heat dissipation member flows through the first flow path.

Another aspect of the present disclosure provides an induction heating cooking device including: a plate to allow a cooking container to be placed thereon; a heating device configured to heat the cooking container by receiving a driving current from a printed circuit board; a user interface to receive a user input for operating the heating device; a heat dissipation member disposed below the user interface and including a heat absorption portion provided to absorb heat generated from the printed circuit board, and a heat dissipation portion provided to release the heat absorbed from the printed circuit board; and a cooling fan configured to generate an airflow for cooling the heat dissipation member. The induction heating cooking device includes a branch guide for guiding a portion of the airflow generated by the cooling fan to the user interface. The heat dissipation portion includes: an inlet portion into which another portion of an airflow generated from the cooling fan is introduced; an outlet portion through which the introduced airflow is discharged; and a first flow path provided to allow the inlet portion and the outlet portion to communicate with each other. The branch guide includes: an extension portion extending along the first flow path; and a curved portion curved from one end of the extension portion adjacent to the outlet portion toward an inside of the user interface so as to be positioned above the outlet portion.

Another aspect of the present disclosure provides an induction heating cooking device including: a plate to allow a cooking container to be placed thereon; a heating device configured to heat the cooking container by receiving a driving current from a printed circuit board; a user interface to receive a user input for operating the heating device; a heat dissipation member disposed below the user interface and configured to absorb and release heat generated from the printed circuit board, and including an inlet portion into which an airflow receiving heat released from the printed circuit board is introduced, and an outlet portion into which the airflow is discharged; and a cooling fan configured to generate an airflow for cooling the user interface and the heat dissipation member. The induction heating cooking device includes: a first duct provided to cover the heat dissipation member to guide a portion of the airflow generated by the cooling fan to the heat dissipation member, and a second duct provided to guide another portion of the airflow generated by the cooling fan to the user interface, disposed between the outlet portion and the user interface, and partitioned from the first duct.

### Advantageous Effects

An airflow may flow into an inside of a user interface device through a branch guide, thereby allowing the user interface device to be effectively cooled.

Further, deterioration of a user interface device may be prevented by cooling the user interface device, thereby extending a service life of an induction heating cooking device.

Further, a branch guide includes a curved portion that is curved at an upper side of an outlet portion of a heat dissipation member, and thus the branch guide may expose the outlet portion to an outside without covering the outlet portion. Accordingly, heat exchange effect of the heat dissipation member may be not impaired.

Further, a branch guide is positioned at a height corresponding to a first heat dissipation fin located at an uppermost position among a plurality of heat dissipation fins, and thus the branch guide may expose an outlet portion of a heat dissipation member to an outside without covering the outlet portion. Accordingly, heat exchange effect of the heat dissipation member may be not impaired.

Further, a branch guide includes an insulating material, and thus an airflow flowing through the branch guide may not be heated even when placed adjacent to a heat dissipation member, thereby allowing a user interface device to be effectively cooled.

Additional aspects of the disclosure will be set forth in part in the description which follows and, in part, will be obvious from the description, or may be learned by practice of the disclosure.

### DESCRIPTION OF DRAWINGS

FIG. 1 is a view illustrating an induction heating cooking device according to one embodiment.

FIG. 2 is an exploded view of the induction heating cooking device according to one embodiment.

FIG. 3 is a view illustrating a main module separated in the induction heating cooking device according to one embodiment.

FIG. 4 is an exploded view of the main module of FIG. 3 according to one embodiment.

FIG. 5 is a view of the main module of FIG. 3 from a different angle according to one embodiment.

FIG. 6 is an exploded view of the main module of FIG. 5 according to one embodiment.

FIG. 7 is an enlarged front view of a portion of the main module of FIG. 3 according to one embodiment.

FIG. 8 is a cross-sectional view of the main module of FIG. 7 taken along a line a-a′ according to one embodiment.

FIG. 9 is a cross-sectional view of a portion of a main module in an induction heating cooking device according to one embodiment taken along the line a-a′ according to one embodiment.

FIG. 10 is an enlarged front view of a portion of a main module in an induction heating cooking device according to one embodiment.

FIG. 11 is a cross-sectional view of the main module of FIG. 10 taken along a line a-a′ according to one embodiment.

### MODES OF THE INVENTION

Embodiments described in the disclosure and configurations shown in the views are merely examples of the embodiments of the disclosure, and may be modified in various different ways at the time of filing of the present application to replace the embodiments and views of the disclosure.

In addition, the same reference numerals or signs shown in the views of the disclosure indicate elements or components performing substantially the same function.

Also, the terms used herein are used to describe the embodiments and are not intended to limit and/or restrict the disclosure. The singular forms “a,” “an” and “the” are intended to include the plural forms as well, unless the context clearly indicates otherwise. In this disclosure, the terms “including”, “having”, and the like are used to specify features, numbers, steps, operations, elements, components, or combinations thereof, but do not preclude the presence or addition of one or more of the features, numbers, steps, operations, elements, components, or combinations thereof.

It will be understood that, although the terms first, second, third, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

In the following detailed description, the terms of “front”, “rear”, “left”, “right”, “upper”, “lower”, and the like may be defined by the views, but the shape and the location of the component is not limited by the term.

When an element is said to be “connected”, “coupled”, “supported” or “contacted” with another element, this includes not only when elements are directly connected, coupled, supported or contacted, but also when elements are indirectly connected, coupled, supported or contacted through a third element.

Throughout the description, when an element is “on” another element, this includes not only when the element is in contact with the other element, but also when there is another element between the two elements.

In referring to a rotational direction, the clockwise direction may be expressed as a first direction, and the counterclockwise direction, which is the opposite of the first direction, may be expressed as a second direction. While such expressions may be commonly used to describe specific details for implementing the present disclosure, the rotational direction of the components of the present disclosure is not limited by these terms.

Hereinafter an induction heating cooking device according various embodiments will be described in detail with reference to the accompanying views.

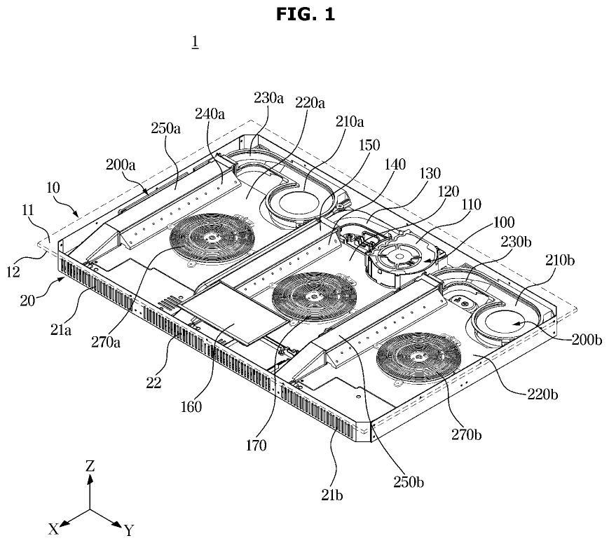

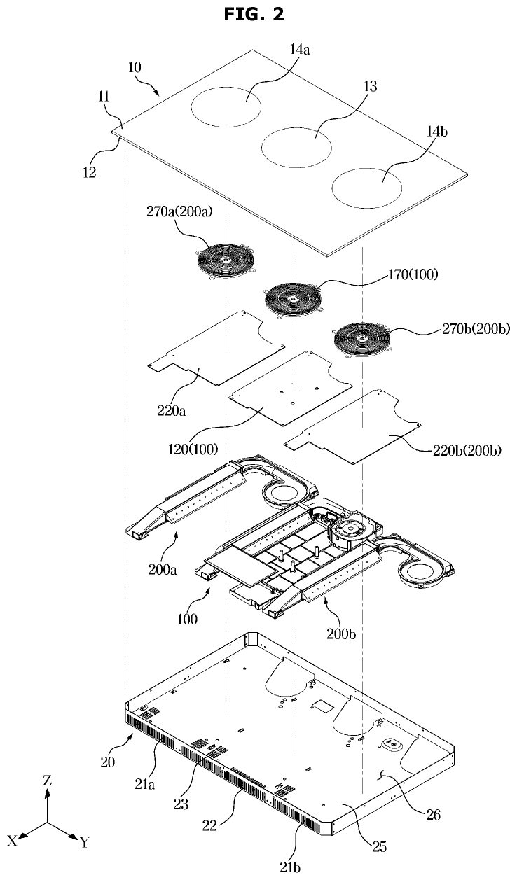

FIG. 1 is a view illustrating an induction heating cooking device according to one embodiment. FIG. 2 is an exploded view of the induction heating cooking device according to one embodiment.

Referring to FIGS. 1 and 2, an induction heating cooking device 1 may include a plate 10 on which a cooking container (not shown) is placed, and a case 20 covered by the plate 10 and provided to accommodate other components.

For convenience of description, the plate 10 in FIG. 1 is illustrated with a dotted line. For example, the plate 10 may include a flat shape to allow the cooking container to be placed thereon.

An upper surface 11 of the plate may be in contact with the cooking container, and a lower surface 12 of the plate may be positioned to face the case 20 and in contact with the case 20.

For example, the plate 10 may include a reinforced glass material such as ceramic glass. For example, the plate 10 may include a heat-resistant material.

The plate 10 may include guide marks 13, 14a, and 14b in which heating devices 170, 270a, and 270b described later are located. When the plate 10 covers the case 20, the guide marks 13, 14a, and 14b may be disposed at a position corresponding to a position where the heating devices 170, 270a, and 270b are disposed.

A user can check the locations of the heating devices 170, 270a, and 270b through the guide marks 13, 14a, 14b and dispose the cooking container on the heating devices 170, 270a, and 270b.

In the drawing, it is illustrated that there are three guide marks 13, 14a, and 14b formed on the plate 10, but this is merely an example. The number and shape of the guide marks 13, 14a, and 14b may be varied in correspondence with the number of heating devices 170, 270a, and 270b.

The case 20 may include a case body 25 forming an outer shape and an accommodating portion 26 formed on an inner side of the case body 25 so as to accommodate components of the induction heating cooking device 1.

For example, the case body 25 may include a hexahedron shape that is open toward an upper side. The accommodating portion 26 formed on the inner side of the case body 25 may be in communication with the outside due to the shape of the case body 25 that is open toward the upper side.

The plate 10 may be coupled to the case 20 to allow the lower surface 12 of the plate to face the accommodating portion 26, and the plate 10 may distinguish the accommodating portion 26 from an external space (S).

For example, the induction heating cooking device 1 may include a main module 100 configured to heat a cooking container and accommodated in the accommodating portion 26, a first module 200a and a second module 200b.

In the drawing, it is illustrated that configurations for heating the cooking container are three modules such as the main module 100, the first module 200a, and the second module 200b, but this is merely an example. The number of modules may be varied depending on the purpose and use.

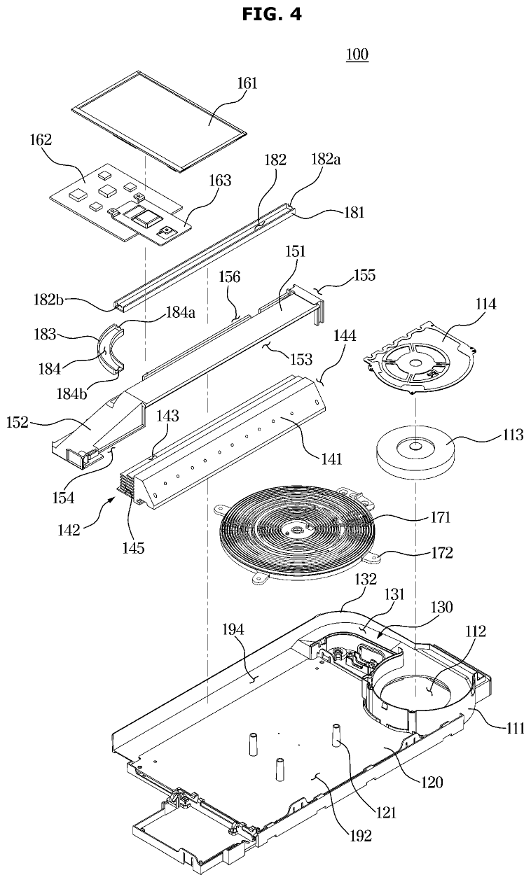

For example, the main module 100 may include a heating device 170 configured to heat a cooking container by receiving a driving current from a printed circuit board 120, a heat dissipation member 140 provided to absorb and release heat, and a fan assembly 110 configured to generate an airflow to cool the heat dissipation member 140. The heating device 170 may include a heating coil 171 (refer to FIG. 4).

The following description is based on the fact that the heat dissipation member 140 absorbs and releases heat generated from the printed circuit board 120. However, it should be understood that the heat dissipation member 140 may be configured to absorb and release heat generated from the heating device 170, as well as absorb and release various types of heat generated inside the induction heating cooking device.

For example, the heat dissipation member 140 may be configured to exchange heat with the printed circuit board 120 and to receive and dissipate heat generated from the printed circuit board 120.

The printed circuit board 120 may supply a driving current to the heating device 170 so as to allow heat to be generated in the heating device 170. Particularly, the printed circuit board 120 may supply a driving current that changes over time, i.e., an alternating current, to the heating device 170. When the heating device 170 receives an alternating current, a magnetic field that changes in magnitude and direction over time may be induced around the heating coil 171.

Due to the magnetic field changing over time, eddy currents (EI) rotating around the magnetic field may be generated in the cooking container.

As mentioned above, a phenomenon in which eddy currents (EI) are generated due to a time-varying magnetic field is referred to as electromagnetic induction. Due to the eddy currents (EI), electrical resistance heat may be generated in the cooking container, and electrical resistance heat is the heat generated in a resistor when current flows through the resistor, and is referred to as Joule heat. As described above, the cooking container may be heated by electrical resistance heat, and food contained in the cooking container may be heated.

In a process in which the printed circuit board 120 supplies a driving current to the heating device 170, heat may be generated in the printed circuit board 120.

The heat dissipation member 140 may be configured to receive heat generated from the printed circuit board 120.

For example, the printed circuit board 120 may include a substantially quadrangle PCB and electronic elements mounted on the PCB board. For example, the electronic elements may include a switching element, an integrated circuit element, etc., for supplying a driving current to the heating device 170.

For example, the heat dissipation member 140 may be disposed to be in contact with the printed circuit board 120 and may absorb heat generated from the electronic elements of the printed circuit board 120.

For example, the heat dissipation member 140 may be disposed on a lateral portion of the printed circuit board 120, and the fan assembly 110 may be disposed at a rear side of the printed circuit board 120.

The fan assembly 110 may generate an airflow that cools the heat dissipation member 140. For example, the main module 100 may include a guide duct 130 provided to connect the fan assembly 110 and the heat dissipation member 140 so as to allow an airflow to flow from the fan assembly 110 to the heat dissipation member 140.

For example, the guide duct 130 may include a curved shape to connect the fan assembly 110 disposed at the rear side of the printed circuit board 120 and the heat dissipation member 140 disposed at the lateral portion of the printed circuit board 120.

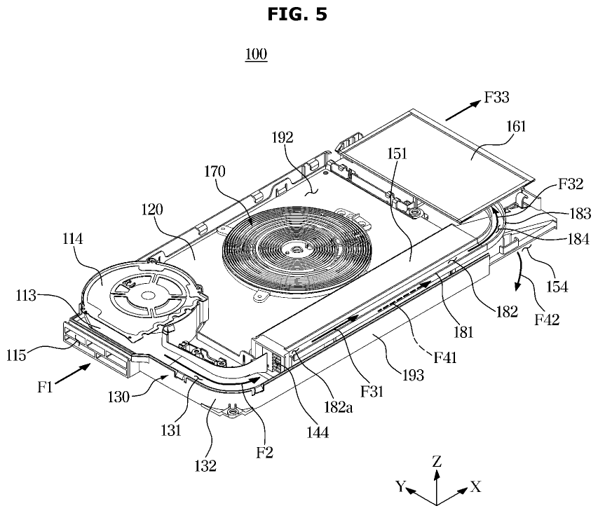

For example, the curved shape may include a convex shape in a direction away from the printed circuit board 120. Accordingly, the airflow generated from the fan assembly 110 may flow to the heat dissipation member 140 through the guide duct 130 (F2, refer to FIG. 5).

The main module 100 may include a cover duct 150 provided to cover the heat dissipation member 140. The cover duct 150 may guide a portion of the airflow generated from a cooling fan 113 to the heat dissipation member 140. For example, the cover duct 150 may be referred to as a first duct 150 in that it is provided to allow a portion of the airflow from the cooling fan 113 to flow. FIG. 1 also illustrates cover ducts 250a and 250b where air from the cooling fan may flow.

For example, an inside 153 of the cover duct may communicate with an inside of the guide duct 130 so as to receive the airflow generated from the fan assembly 110.

Because the cover duct 150 covers the heat dissipation member 140, an airflow (F41, refer to FIG. 5) flowing in the heat dissipation member 140 may be covered by the cover duct 150 and may not leak out to the outside. Therefore, the airflow may effectively come into contact with the heat dissipation member 140 and cool the heat dissipation member 140.

For example, the cover duct 150 may include a lead portion 152 that guides an airflow, which is heat-exchanged with the heat dissipation member 140, to the lower surface of the case 20. The case 20 may include a lower case hole 23 formed on a lower surface of the case body 25 and communicating with an inside of the lead portion 152.

The lower case hole 23 may be formed by penetrating the lower surface of the case body 25 so as to allow the inside of the lead portion 152 and the external space (S) to communicate with each other. An airflow heated by heat-exchange with the heat dissipation member 140 may be guided to the lower surface of the case 20 by the lead portion 152. The airflow guided to the lower surface of the case 20 may pass through the lower case hole 23 and finally be discharged to the external space (S) (F42, refer to FIG. 5).

For example, the case 20 may include a front case hole 22 formed on a front side of the case body 25. The front case hole 22 may be formed to penetrate the case body 25 so as to allow the accommodating portion 26 of the case 20 and the external space (S) to communicate with each other.

For example, the case 20 may include a first case hole 21a and a second case hole 21b formed on the left and right sides, respectively, of the front case hole 22. The first case hole 20 and the second case hole 21b may also allow the accommodating portion 26 and the external space (S) to communicate with each other. Descriptions of the front case hole 22, the first case hole 21a, and the second case hole 21b will be provided later.

The above-described method of heating the heating device 170 of the main module 100, the arrangement structure with the heat dissipation member 140 for cooling the printed circuit board 120, the method of cooling the heat dissipation member 140 by the airflow generated from the fan assembly 110, and the process of discharging the heat-exchanged airflow to the external space (S) may be applied in the same way to the following first module 200a and second module 200b.

For example, the first module 200a may include a first heating device 270a configured to heat a cooking container by receiving a driving current from a first printed circuit board 220a, a first heat dissipation member 240a provided to exchange heat with the first printed circuit board 220a so as to receive and dissipate heat generated from the first printed circuit board 220a, and a first fan assembly 210a configured to generate an airflow to cool the first heat dissipation member 240a. For example, the first module 200a may include a first guide duct 230a connecting the first fan assembly 210a and the first heat dissipation member 240a.

For example, the second module 200b may include a second heating device 270b configured to heat a cooking container by receiving a driving current from the second printed circuit board 220b, a second heat dissipation member 240b provided to exchange heat with the second printed circuit board 220b so as to receive and dissipate heat generated from the second printed circuit board 220b, and a second fan assembly 210b configured to generate an airflow to cool the second heat dissipation member 240b. For example, the second module 200b may include a second guide duct 230b connecting the second fan assembly 210b and the second heat dissipation member 240b.

For example, the first module 200a and the second module 200b may be disposed on the left and right sides of the main module 100, respectively.

The induction heating cooking device 1 may include a user interface 160 configured to receive a user input for operating the heating device 170, the first heating device 270a, and the second heating device 270b and provided to display information regarding the induction heating cooking device 1.

For example, the user interface 160 may include an inputter 161 configured to receive an input from a user and an outputter 161 provided to display information regarding the induction heating cooking device 1.

The inputter 161 of the user interface 160 may include a Graphical User Interface (GUI), i.e., a software device, such as a touch pad for user input. The touch pad may be implemented as a touch screen panel and may form a layered structure with the outputter 161 of the user interface 160.

The user interface 160 may include a cathode ray tube, a digital light source processing panel, a plasma display panel, a liquid crystal display panel, an electroluminescent panel, an electrophoretic display panel, an electrochromic display panel, a light-emitting diode panel, or an organic light-emitting diode panel to display information of the induction heating cooking device 1, but is not limited thereto.

As mentioned above, when composed of a touch screen panel that forms a layered structure with a touch pad, the outputter 161 of the user interface 160 may also be used as the inputter 161. For convenience of description, the following description will assume that the user interface 160 is composed of a touch screen panel and performs both the roles of the inputter 161 and the outputter 161.

For example, the user interface 160 may be disposed in such a way that left and right positions thereof correspond to those of the main module 100 with respect to the case 20. Alternatively, the user interface 160 may be disposed between the first module 200a and the second module 200b.

For example, the user interface 160 may be installed on the lower surface 12 of the plate. Accordingly, the user interface 160 may be disposed on an upper side of the accommodating portion 26 of the case 20, so as to be located above the heating device 170, the heat dissipation member 140, and the cover duct provided to cover the heating device 170 and the heat dissipation member 140.

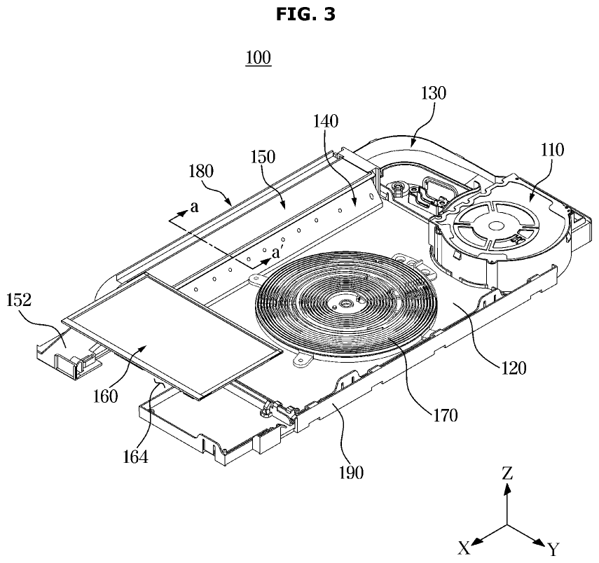

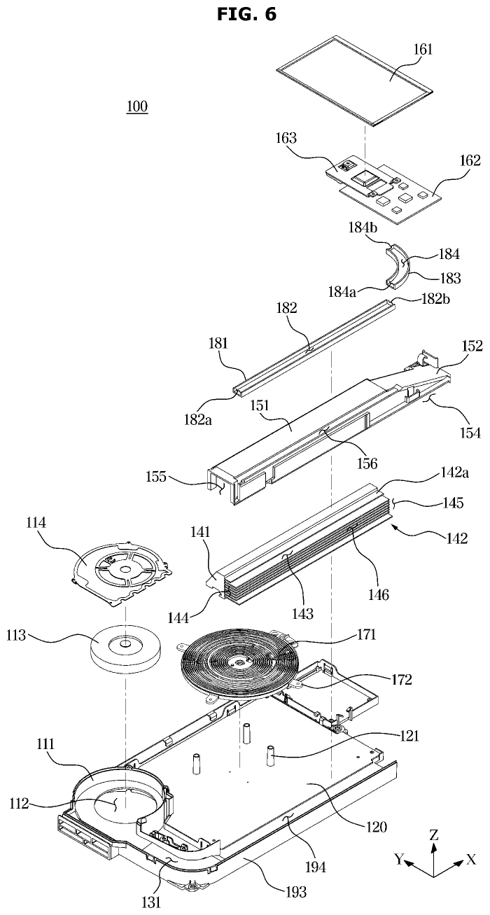

FIG. 3 is a view illustrating a main module separated in the induction heating cooking device according to one embodiment. FIG. 4 is an exploded view of the main module of FIG. 3. FIG. 5 is a view of the main module of FIG. 3 from a different angle. FIG. 6 is an exploded view of the main module of FIG. 5.

Referring to FIGS. 3 to 6, the main module 100 may include a module case 190 provided to accommodate the heating device 170, the cooling fan 113, the heat dissipation member 140, and the printed circuit board 120. The module case 190 may be accommodated in the accommodating portion 26 and placed on the case 20. For example, the module case 190 of the main module 100 may be disposed on a central side of the accommodating portion 26 in the left and right direction (+−Y direction).

The module case 190 may include a module case accommodating portion 192 formed therein. The module case accommodating portion 192may accommodate the heating device 170, the heat dissipation member 140, the printed circuit board 120, the cover duct 150, etc.

The module case 190 may include a plurality of support protrusions 121 protruding upward (+Z side). The plurality of support protrusions 121 may protrude upward from a lower surface of the module case 190. The plurality of support protrusions 121 may protrude upward and penetrate the printed circuit board 120.

The plurality of support protrusions 121 may be spaced apart from each other and arranged to support the heating device 170. For example, the plurality of support protrusions 121 may be arranged along an outer circumference of the heating coil 171 of the heating device 170.

The fan assembly 110 may include the cooling fan 113 configured to generate an airflow, a fan housing 111 having a shape that is open toward the upper side to form a fan accommodating groove 112 into which the cooling fan 113 is accommodated, and a fan housing cover 114 provided to be coupled to the fan housing 111 to cover the fan accommodating groove 112.

For example, the cooling fan 113 may include a sirocco fan, but is not limited thereto.

For example, the fan housing 111 may be disposed at a rear side of the module case 190. For example, the fan housing 111 may be disposed at the rear side of the printed circuit board 120 placed on the module case 190.

The fan housing 111 may include an airflow supply port 115 through which an airflow (F1) is supplied from an outside to an inside of the fan housing 111 as the cooling fan 113 rotates. The airflow (F1) supplied into the inside of the fan housing 111 through the airflow supply port 115 may be discharged to the guide duct 130 by the cooling fan 113 (F2).

For example, the airflow supply port 115 may be disposed at the rear side of the fan housing 111.

The fan housing 111 may include a roughly hollow cylindrical shape. The fan accommodating groove 112 may be a hollow portion formed on an inner side of the fan housing 111. The fan housing 111 may protrude upward to separate the fan accommodating groove 112 from the module case accommodating portion 192.

For example, the fan housing 111 may be formed integrally with the module case 190. For example, the fan housing 111 may be formed as a partial configuration of the module case 190.

A flow path forming portion 194 may be provided on a lateral portion of the module case 190. The flow path forming portion 194 may extend along the module case 190 in the front and rear direction (+−X direction). For example, the flow path forming portion 194 may be a portion of the module case accommodating portion 192. As will be described later, the heat dissipation member 140 and the cover duct 150 may be located in the flow path forming portion 194.

The heat dissipation member 140 and the cover duct 150 may be placed on the module case 190. The heat dissipation member 140 and the cover duct 150 may be placed on the module case 190 so as to extend in the front and rear direction (+−X direction). The cover duct 150 may be disposed in such a way that the lead portion 152 faces forward (+X direction).

As described above, the guide duct 130 may be formed to connect the fan assembly 110, the heat dissipation member 140, and the cover duct 150. The guide duct 130 may include a guide duct body 132 forming an outer shape, and a guide duct flow path 131 extending along the guide duct body 132 inside the guide duct body 132. The guide duct body 132 and the guide duct flow path 131 may be formed to be curved.

The cooling fan 113 may rotate to generate an airflow. The airflow generated by the cooling fan 113 may be discharged to the outside of the fan housing 111, and the discharged airflow (F2) may flow into the guide duct flow path 131. The airflow flowing into the guide duct flow path 131 may be guided to the heat dissipation member 140 (F41).

For example, the guide duct body 132 may be formed integrally with the module case 190. For example, the guide duct body 132 may be a partial configuration of the module case 190.

The heating device 170 may include the heating coil 171 configured to generate heat, and a plurality of coupling protrusions 172 arranged along an outer circumference of the heating coil 171. For example, the plurality of coupling protrusions 172 may be formed to protrude radially from the heating coil 171.

The plurality of coupling protrusions 172 may each be coupled to the plurality of supporting protrusions 121 of the aforementioned module case 190, and the heating coil 171 may be stably supported on the module case 190.

The heat dissipation member 140 may be disposed in the flow path forming portion 194 of the module case 190. For example, the heat dissipation member 140 may be disposed to be located on the lower side (−Z side) of the user interface 160.

For example, the heat dissipation member 140 may include a heat absorption portion 141 provided to absorb heat from the printed circuit board 120, and a heat dissipation portion 142 provided to receive the heat, which is absorbed by the heat absorption portion 141, and release the received heat to the outside. For example, the heat dissipation portion 142 may be formed to protrude from the heat absorption portion 141. For example, the heat absorption portion 141 and the heat dissipation portion 142 may be formed integrally.

The heat dissipation member 140 may be disposed in such a way that the heat absorption portion 141 faces the printed circuit board 120. When the heat absorption portion 141 faces the printed circuit board 120, the heat dissipation portion 142 may be located on the opposite side of the printed circuit board 120 relative to the heat absorption portion 141.

For example, the heat absorption portion 141 may include a heat absorption block 141 provided to absorb heat from the printed circuit board 120 and extend in the front and rear direction (+−X direction). For example, the heat absorption block 141 may be disposed to be in contact with the printed circuit board 120.

For example, the heat dissipation portion 142 may be a heat dissipation fin 142 protruding from a lateral portion of the heat absorption block 141. The heat dissipation fin 142 may include a plurality of heat dissipation fins 142 (142a, 142b, 142c, 142d, 142e) protruding from the heat absorption block 141 and arranged in the up and down direction. The plurality of heat dissipation fins 142 may receive heat absorbed by the heat absorption block 141 and release the received heat to the outside.

For example, the plurality of heat dissipation fins 142 may be extended in the front and rear directions along the heat absorption block 141.

For example, the plurality of heat dissipation fins 142 may be arranged to come into contact with the airflow (F41) guided by the guide duct 130. The airflow (F41) flowing to the heat dissipation member 140 may absorb the heat emitted by the plurality of heat dissipation fins 142.

The plurality of heat dissipation fins 142 may include an inlet portion 144 into which the airflow (F2) generated from the cooling fan 113 is introduced. The inlet portion 144 may be formed in such a way that each end of the plurality of heat dissipation fins 142 adjacent to the cooling fan 113 is spaced apart from one another. In other words, the airflow (F2) may flow into a space, in which the plurality of heat dissipation fins 142 is spaced apart from one another, and come into contact with the plurality of heat dissipation fins 142.

The plurality of heat dissipation fins 142 may include an outlet portion 145 through which the airflow (F41) introduced into the inlet portion 144 is discharged. The outlet portion 145 may be formed in such a way that each other end of the plurality of heat dissipation fins 142 is spaced apart from each other.

The heat dissipation member 140 may include a first flow path 146 connecting the inlet portion 144 and the outlet portion 145. The first flow path 146 may extend along the plurality of heat dissipation fins 142.

The airflow (F41) introduced into the inlet portion 144 may absorb heat emitted by the plurality of heat dissipation fins 142 while flowing along the first flow path 146, and the airflow may be discharged to the outlet portion 145 (F42). Accordingly, the heat dissipation member 140 may be cooled.

For example, a first heat dissipation fin 142a at an uppermost position among the plurality of heat dissipation fins 142 may have a shorter length protruding from the heat absorption block 141 than the other plurality of heat dissipation fins 142 excluding the first heat dissipation fin 142a. Accordingly, the heat dissipation member 140 may include a spare space 143 formed in such a way that the first heat dissipation fin 142a protrudes shorter from the heat absorption block 141 than the remaining heat dissipation fins excluding the first heat dissipation fin 142a.

The spare space 143 may be formed at a height corresponding to a height at which the first heat dissipation fin 142a is located. The spare space 143 may be a space enclosed by one end of the first heat dissipation fin 142a protruding from the heat absorption block 141 and a side surface of the second heat dissipation fin positioned below the first heat dissipation fin 142a. A description of the spare space 143 will be provided later.

The cover duct 150 may cover the heat dissipation member 140. For example, the cover duct 150 may cover the plurality of heat dissipation fins 142. The first flow path 146 may be covered by the cover duct 150 and partitioned from a module accommodating portion 192 of the module case 190. Accordingly, the airflow (F41) flowing in the first flow path 146 may flow stably without leaking out to the outside.

The cover duct 150 may include a cover duct body 151 extending in the front and rear direction and forming an outer shape, and the lead portion 152 positioned in front of the cover duct body 151. A cover duct flow path 153 may be formed in the inside 153 of the cover duct body. The cover duct flow path 153 may extend in a longitudinal direction of the cover duct body 151. The cover duct flow path 153 may refer to an inner hollow space of the cover duct 150.

The cover duct 150 may include a duct inlet 155 formed at one end of the cover duct body 151 facing the cooling fan 113 and communicating with one end of the cover duct flow path 153, and a duct outlet 154 formed at a lower end of the lead portion 152 and communicating with the other end of the cover duct flow path 153.

The duct inlet 155 and the duct outlet 154 may be formed to communicate with the cover duct flow path 153.

For example, the cover duct 150 may include a cutout portion 156 formed by cutting one side of the cover duct body 151. The cutout portion 156 may be formed by penetrating one side of the cover duct body 151 to communicate with the outside through the cover duct flow path 153.

As will be described later, when the heat dissipation member 140 is covered by the cover duct 150, the spare space 143 and the cutout portion 156 may communicate with each other. Because the spare space 143 is positioned at one end of the first heat dissipation fin 142a which protrudes from the heat absorption block 141 in a direction away from the printed circuit board 120, the cutout portion 156 may also be located on the opposite side of the printed circuit board 120 with respect to the heat dissipation member 140.

When the cover duct 150 covers the heat dissipation member 140, the plurality of heat dissipation fins 142 may be arranged so as to allow the spare space 143 to communicate with the cutout portion 156. In other words, the cutout portion 156 may be placed in the module case 190 so as to face the opposite side of the printed circuit board 120 to cover the heat dissipation member 140.

When the heat dissipation member 140 is disposed in the flow path forming portion 194, the cover duct 150 may be disposed in the flow path forming portion 194 while covering the heat dissipation member 140. The cover duct 150 may be placed in the module case 190.

The cover duct 150 may be disposed in such a way that the heat dissipation member 140 is accommodated in the cover duct flow path 153 so as to cover the heat dissipation member 140. When the cover duct 150 accommodates the heat dissipation member 140, the duct inlet 155 of the cover duct 150 may be in communication with the inlet portion 144 of the heat dissipation member 140, and the duct outlet 154 of the cover duct 150 may be in communication with the outlet portion 145 of the heat dissipation member 140.

The airflow (F2) generated from the cooling fan 113 may flow into the duct inlet 155 and may flow into the inlet portion 144 of the heat dissipation member 140. Thereafter, the airflow (F41), which flows in the first flow path 146 and exchanges heat with the plurality of cooling fins, may be discharged through the outlet portion 145 and then be discharged to the outside of the cover duct 150 through the cover duct outlet 154 (F42).

The airflow discharged to the outside of the cover duct 150 may be introduced into the lower case hole 23 of the case 20 and finally discharged into the external space (S).

The user interface 160 may include a panel portion 161 including the inputter 161 and the outputter 161, an electronic component portion 162 electrically connected to the panel portion 161 and configured to process a user input signal input to the panel portion 161 and display information on the panel portion 161, and a support portion 163 supporting the panel portion 161.

For example, the user interface 160 may be disposed in such a way that a position thereof corresponds to the printed circuit board 120 in the left and right direction relative to the module case 190. In other words, positions of the user interface 160 and the printed circuit board 120 may correspond to each other in the left and right direction (+−Y direction), and the heat dissipation member 140 and the cover duct 150 may be disposed on a lateral portion of the user interface 160.

For example, the support portion 163 may be coupled to the module case 190 to support the panel portion 161. The panel portion 161 and the electronic component portion 162 may be spaced apart.

For example, the support portion 163 may be disposed between the panel portion 161 and the electronic component portion 162. For example, the support portion 163 and the electronic component portion 162 may be spaced apart.

The panel portion 161 and the support portion 163 may be located above the heat dissipation member 140. The electronic component portion 162 may be positioned at a location corresponding to an upper position of the heat dissipation member 140.

For example, the panel portion 161 may be disposed on the lower surface 12 of the plate. For example, the panel portion 161 may be configured to allow a user to input an input signal on the upper surface 11 of the plate. For example, the panel portion 161 may be configured to allow a user to check the information displayed on the panel portion 161 on the upper surface 11 of the plate.

In a process in which the electronic component portion 162 receives an input signal input to the panel portion 161 and displays information of the induction heating cooking device 1 on the panel portion 161, heat may be generated in the electronic component portion 162.

The induction heating cooking device 1 may include a branch guide 180 for guiding a portion (F31) of the airflow generated from the cooling fan 113 to the user interface 160.

The branch guide 180 may include an extension portion 181 extending in the front and rear direction (+−X direction).

The extension portion 181 may be disposed in such a way that one end thereof faces the cooling fan 113. The branch guide 180 may include a curved portion 183 extending from the other end of the extension portion 181 and curved into an inside of the user interface 160.

The branch guide 180 may be disposed in the spare space 143. Particularly, the extension portion 181 may be inserted into the cutout portion 156 of the cover duct 150 and positioned in the spare space 143.

For example, the branch guide 180 may be inserted into the cutout portion 156 and disposed to come into contact with the cover duct 150. The branch guide 180 and the cover duct 150 may be formed to be separable, but this is merely an example. Alternatively, the branch guide 180 and the cover duct 150 may be formed integrally.

When the branch guide 180 is disposed in the spare space 143, the branch guide 180 may be spaced apart from the plurality of heat dissipation fins 142.

Particularly, the extension portion 181 may be disposed so as not to come into contact with the plurality of heat dissipation fins 142. Accordingly, a phenomenon, in which heat discharged from the plurality of heat dissipation fins is transferred to the extension portion 181, may be minimized.

For example, the branch guide 180 may include an insulating material. Therefore, even when heat is discharged from the plurality of heat dissipation fins, the airflow (F31 and F32) flowing through the branch guide 180 may not be heated.

The extension portion 181 may extend along a longitudinal direction (+−X direction) of the first heat dissipation fin 142a. The extension portion 181 may include an extension flow path 182 formed on an inner side through which an airflow may flow. The extension flow path 182 may extend along a longitudinal direction of the extension portion 181. The extension flow path 182 may be formed to be partitioned from the first flow path 146.

The extension flow path 182 may include an extension flow path entrance 182a formed at one end of the extension flow path 182 adjacent to the cooling fan 113, and an extension flow path exit 182b formed at the other end of the extension flow path.

The extension flow path entrance 182a may be disposed adjacent to the duct inlet 155 of the cover duct 150 and the inlet portion 144 of the heat dissipation member 140. When a portion (F41) of the airflow generated from the cooling fan 113 flows into the inlet portion 144 of the heat dissipation member 140, another portion (F31) of the airflow may flow into the entrance of the extension flow path 182. Thus, another portion (F31) of the airflow from the cooling fan 113 may flow into the extension portion 181 and flow on the extension flow path 182.

The curved portion 183 may include a curved flow path 184 formed on the inner side through which the airflow (F32) may flow. The curved flow path 184 may extend from the other end of the extension flow path 182 into the inside of the user interface 160. The curved flow path 184 may be formed in a curved shape. The curved flow path 184 may be formed to be partitioned from the first flow path 146.

The curved flow path 184 may include a curved flow path entrance 184a formed at one end of the curved flow path 184 and connected to the extension flow path exit 182b, and a curved flow path exit 184b formed at the other end of the curved flow path 184 and connected to the inside of the user interface 160.

Because the extension portion 181 is disposed in the cutout portion 156 and the cutout portion 156 is located on the opposite side of the printed circuit board 120 with respect to the heat dissipation member 140, the extension portion 181 may also be disposed on the opposite side of the printed circuit board 120 with respect to the heat dissipation member 140.

Because the user interface 160 is disposed in such a way that a position thereof corresponds to the printed circuit board 120 in the left and right directions relative to the module case 190, the extension portion 181 may be located on the opposite side of the user interface 160 relative to the heat dissipation member 140.

For example, because the curved portion 183 is curved from the other end of the extension portion 181 to the user interface 160, the curved portion 183 may be formed to extend from the extension portion 181 and surround the heat dissipation member 140.

Particularly, the curved portion 183 may be formed to surround the first heat dissipation fin 142a and the heat absorption block 141. In other words, the curved portion 183 may extend to the user interface 160 while covering the front side of the first heat dissipation fin 142a and the heat absorption block 141.

As will be described later, the airflow generated from the cooling fan 113 may flow into the inside of the user interface 160 through the extension flow path 182 and the curved flow path 184, and may cool the user interface 160 by absorbing heat generated from the electronic component portion 162. A detailed description of the process of the airflow flowing into the inside of the user interface 160 will be provided later.

The user interface 160 may include an outlet 164 through which the airflow (F32) introduced into the user interface 160 is discharged (F33). In the drawing, it is illustrated that the outlet 164 is formed in front of the user interface 160, but this is merely an example. Alternatively, the outlet 164 may be formed in various locations to discharge the airflow from the inside of the user interface 160.

For example, the outlet 164 may communicate with the front case hole 22 of the case 20. Thus, an airflow, which absorbs heat from the electronic component portion 162, may be discharged through the outlet 164 and pass through the front case hole 22 (F33), and accordingly, may finally be discharged into the external space (S).

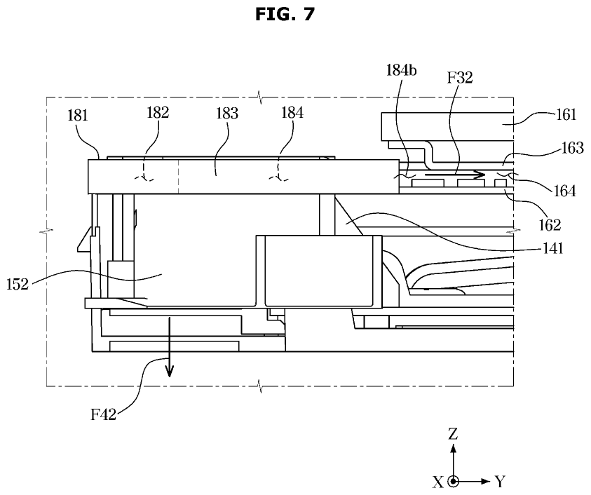

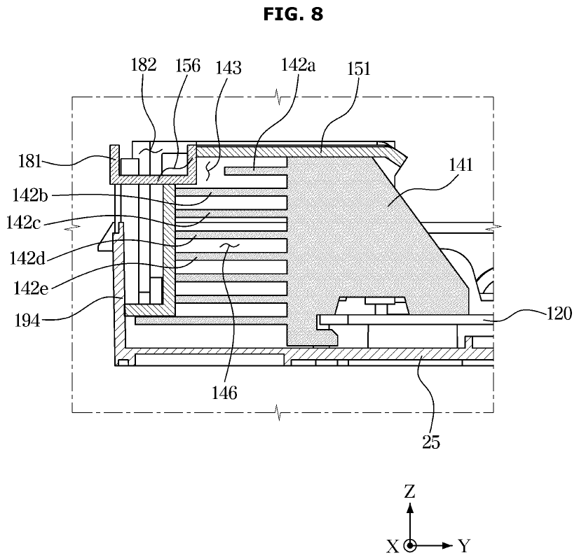

FIG. 7 is an enlarged front view of a portion of the main module of FIG. 3. FIG. 8 is a cross-sectional view of the main module of FIG. 7 taken along a line a-a′.

Referring to FIGS. 7 and 8, as mentioned above, the extension portion 181 and the curved portion 183 may be connected to each other. The extension flow path 182 and the curved flow path 184 may communicate with each other.

A flow path formed by the communication of the extension flow path 182 and the curved flow path 184 may be referred to as second flow paths 182 and 184. A portion of the airflow (F31 and F32) generated from the cooling fan 113 may flow in the second flow paths 182 and 184.

The curved portion 183 may be disposed above the outlet portion 145 so as to allow the outlet portion 145 to be exposed, and may be curved from the extension portion 181 into the inside of the user interface 160. The curved flow path exit 184b may be in communication with the inside of the user interface 160.

Due to the arrangement of the curved portion 183 described above, the curved portion 183 may not obstruct the airflow discharged from the outlet portion 145 of the heat dissipation member 140, and thus the cooling of the heat dissipation member 140 may be performed more smoothly.

The second flow paths 182 and 184 may move a portion of the airflow generated by the cooling fan 113 into the inside of the user interface 160. For example, the inside of the user interface 160 may refer to a space between the electronic component portion 162 and the panel portion 161.

The second flow paths 182 and 184 may be disposed above the first flow path 146. The second flow paths 182 and 184 may be partitioned from the first flow path 146. For example, a height at which the second flow paths 182 and 184 are positioned may be a height corresponding to a height at which the first heat dissipation fin 142a is positioned.

The airflow generated from the cooling fan 113 may flow into the inside of the user interface 160 through the second flow paths 182 and 184 (F32). The airflow (F32) flowing into the inside of the user interface 160 may absorb heat generated from the electronic component portion 162. Accordingly, the user interface 160 may be cooled.

An airflow, which is heat-exchanged with heat generated in the user interface 160, may be discharged to the outside of the user interface 160 through the outlet 164 (F33). Thereafter, the airflow may flow through the front case hole 22 of the case 20 and finally be discharged to the external space (S).

Another portion of the airflow generated by the cooling fan 113 may flow on the first flow path 146 formed by the plurality of heat dissipation fins 142 spaced apart in the up and down direction.

The airflow (F41) flowing in the first flow path 146 may absorb heat released from the plurality of heat dissipation fins 142 and may be discharged to the outside of the heat dissipation member 140 through the outlet portion 145 (F42). Thereafter, the discharged airflow may be guided downward by the lead portion 152 of the cover duct 150 and may be discharged to the external space (S) through the duct outlet 154 and the lower case hole 23.

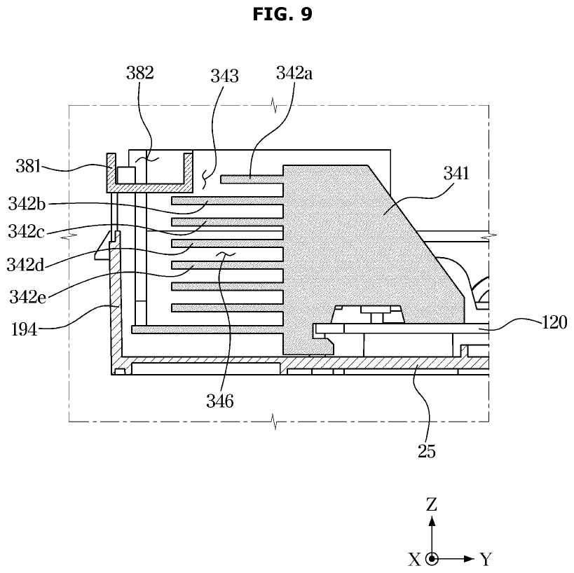

FIG. 9 is a cross-sectional view of a portion of a main module in an induction heating cooking device according to one embodiment taken along the line a-a′. Hereinafter descriptions regarding content that is the same as the above will be omitted.

Referring to FIG. 9, for example, an induction heating cooking device 2 may be configured to operate even when a cover duct does not cover a heat dissipation member 340. In the above case, a branch guide 380 may be disposed in a spare space 343 without being in contact with the cover duct, so as to form second flow paths 382 and 384.

Particularly, the branch guide 380 may be spaced apart from a plurality of heat dissipation fins 342 (342a, 342b, 342c, 342d, 342e) and disposed in the spare space 343. For example, each end of the branch guide 380 may be supported by a module case 390 and disposed in the spare space 343.

The spare space 343 may be located at a height corresponding to a first heat dissipation fin 342a because the first heat dissipation fin 342a is formed to protrude shorter from a heat absorption block 341 than the other heat dissipation fins. That is, the spare space 343 may be located above the other heat dissipation fins excluding the first heat dissipation fin 342a.

Accordingly, even when the branch guide 380 is located in the spare space 343 and a curved portion 383 of the branch guide 380 is curved and extended toward a user interface 360, an outlet portion 345 formed by the spaced-apart heat dissipation fins 342 may not be covered by the curved portion 383. That is, an airflow flowing in a first flow path 346 may be smoothly discharged to the outlet portion 345.

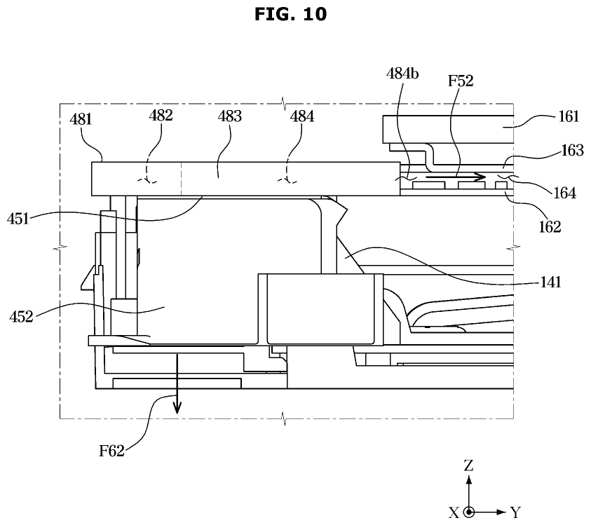

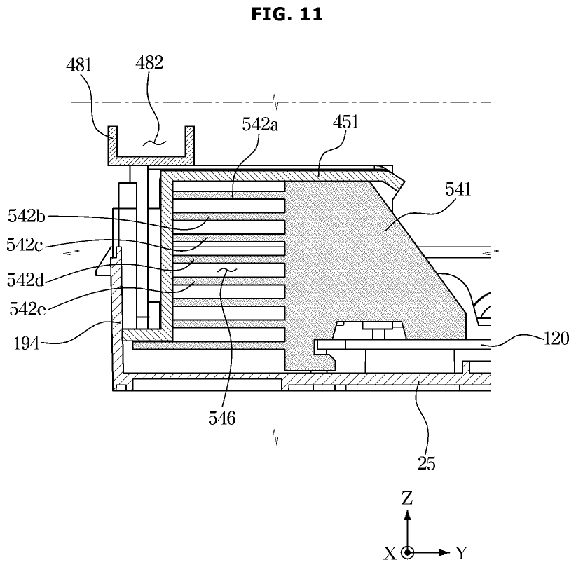

FIG. 10 is an enlarged front view a portion of a main module in an induction heating cooking device according to one embodiment. FIG. 11 is a cross-sectional view of the main module of FIG. 10 taken along a line a-a′. Hereinafter descriptions regarding content that is the same as the above will be omitted.

Referring to FIGS. 10 and 11, a heat dissipation member 440 may include a plurality of heat dissipation fins 442. Each of the plurality of heat dissipation fins 442 may be formed to protrude by the same length from a heat absorption block 444. The plurality of heat dissipation fins 442 may be arranged spaced apart in the up and down direction on the heat absorption block 444. FIG. 11 shows the heat dissipation member may include a plurality of heat dissipation fins (542a, 542b, 542c, 542d, 542e), a heat absorption block 541 and a first flow path 546.

The induction heating cooking device 3 may include a cover duct 450 provided to cover the heat dissipation member 440. The cover duct 450 may cover the plurality of heat dissipation fins 442 so as to allow the plurality of heat dissipation fins 442 to be blocked from a module accommodating portion 492 of a module case 490. For example, each end of the plurality of heat dissipation fins 442 protruding from the heat absorption block 444 may be arranged to be in contact with one surface of the cover duct 450.

The induction heating cooking device 3 may include a branch guide 480 provided to guide an airflow generated from a cooling fan 413 to a user interface 460.

The branch guide 480 may include an extension portion 481 that is placed on an upper surface 451 of the cover duct 450 and extends in the front and rear direction, and a cover portion that is curved to connect an inside of the user interface 460 from one end of the extension portion 484 facing forward.

For example, when the branch guide 480 is placed on the upper surface of the cover duct 450, a height, at which second flow paths 482 and 484 formed by the branch guide 480 are located, may correspond to a height of an internal space of the user interface 460.

The second flow paths 482 and 484 formed by the branch guide 480 may be positioned above a first flow path 446 formed by the plurality of heat dissipation fins 442 spaced apart from each other.

Therefore, even when a curved flow path 484 of a curved portion 483 forming a portion of the second flow paths 482 and 484 is curved into an inside of the user interface 460, the curved flow path 484 may not cover an outlet portion 445 formed by one end of the plurality of heat dissipation fins 442. Therefore, an airflow flowing in the first flow path 446 may be smoothly discharged to the outlet portion 445.

An induction heating cooking device 1 according to one embodiment may include a plate 10 for placing a cooking container thereon, a heating device 170 configured to heat the cooking container by receiving a driving current from a printed circuit board 120, and a user interface 160 for receiving a user input for operating the heating device. The induction heating cooking device 1 may include a heat dissipation member 140 disposed below the user interface 160 and configured to exchange heat with the printed circuit board 120, and a cooling fan 113 configured to generate an airflow for cooling the heat dissipation member 140. The induction heating cooking device 1 may include a branch guide 180 for guiding a portion of the airflow generated by the cooling fan 113 to the user interface 160. The branch guide 180 may include second flow paths 182 and 184 disposed above and separated from a first flow path 146 through which air for cooling the heat dissipation member 140 flows.

The heat dissipation member 140 may include a heat absorption block 141 provided to absorb heat from the printed circuit board 120, and a plurality of heat dissipation fins 142 protruding from a lateral portion of the heat absorption block 141 and arranged in an up and down direction, provided to release heat absorbed by the heat absorption block 141 and provided to come into contact with the airflow generated by the cooling fan 131. The second flow paths 182 and 184 may be disposed at a height corresponding to a height at which a first heat dissipation fin 142a, which is located at an uppermost position among the plurality of heat dissipation fins 142, is disposed.

The plurality of heat dissipation fins 142 may include an inlet portion 144 into which an airflow generated from the cooling fan 113 is introduced. The inlet portion 144 may be formed in such a way that each end of the plurality of heat dissipation fins 142 adjacent to the cooling fan 113 is spaced apart from each other. The plurality of heat dissipation fins 142 may include an outlet portion 145 through which the introduced airflow is discharged. The outlet portion 145 may be formed in such a way that the other end of the plurality of heat dissipation fins 142 is spaced apart from each other. The first flow path 146 may be formed to allow the inlet portion 144 and the outlet portion 145 to communicate with each other.

The branch guide 180 may include an extension portion 181 extending along a longitudinal direction of the first heat dissipation fin 142a, and a curved portion 183 formed to surround the first heat dissipation fin 142a and the heat absorption block 141, positioned above the outlet portion 145 to allow the outlet portion 145 to be exposed, and curved from the extension portion 181 toward an inside of the user interface 160.

The heat dissipation member 140 may include a spare space 143 formed in such a way that the first heat dissipation fin 142a protrudes shorter from the heat absorption block 141 than the remaining heat dissipation fins excluding the first heat dissipation fin 142a. The branch guide 180 may be disposed in the spare space 143.

The branch guide 180 may be spaced apart from the plurality of heat dissipation fins 142 in response to the branch guide 180 being disposed in the spare space 143.

The induction heating cooking device 1 may further include a case 20 covered by the plate 10 and provided to accommodate the cooling fan 113, the branch guide 180, and the user interface 160. The user interface 160 may include an outlet 164 through which an airflow introduced into the inside of the user interface 160 is discharged. The case 20 may include a case hole provided to allow the outlet 164 to communicate with an outside so as to discharge an airflow discharged from the user interface 160 to the outside.

The case hole may be formed to allow the outlet portion 145 of the heat dissipation member 140 to communicate with the outside.

The branch guide 180 may include an insulating material.

The induction heating cooking device 1 may further include a cover duct 150 provided to cover the heat dissipation member 140 to guide another portion of the airflow generated from the cooling fan 113 to the heat dissipation member 140. The cover duct 150 and the branch guide 180 may be arranged to be in contact with each other.

The cover duct 150 may include a cutout portion 156 formed to communicate with the spare space 143. The branch guide 180 may be inserted into the cutout portion 156 and disposed in the spare space 143.

The cover duct 150 and the branch guide 180 may be integrally formed.

An induction heating cooking device 3 may further include a cover duct 350 provided to cover a heat dissipation member 340 to guide another portion of the airflow generated from a cooling fan 313 to the heat dissipation member 340. A branch guide 380 may be arranged to be placed on an upper surface of the cover duct 350.

The induction heating cooking device 1 may further include a case 20 covered by the plate 10 and provided to accommodate the cooling fan 113, the branch guide 180, and the user interface 160. The cover duct 150 may further include a lead portion 152 provided to guide the airflow discharged from the outlet portion 145 to a lower surface of the case 20. The case 20 may include a case hole provided to allow the lead portion 152 to communicate with the outside to discharge an airflow discharged from the outlet portion 145 to the outside.

The branch guide 180 may include an insulating material.

An induction heating cooking device 1 according to one embodiment may include a plate 10 for placing a cooking container thereon, a heating device 170 configured to heat the cooking container by receiving a driving current from a printed circuit board 120, a user interface 160 for receiving a user input for operating the heating device 170, a heat dissipation member 140 disposed below the user interface 160 and including a heat absorption portion 141 provided to absorb heat generated from the printed circuit board 120, and a heat dissipation portion provided to release the heat absorbed from the printed circuit board 120, and a cooling fan 113 configured to generate an airflow for cooling the heat dissipation member 140. The induction heating cooking device 1 may include a branch guide 180 for guiding a portion of the airflow generated by the cooling fan 113 to the user interface 160. The heat dissipation portion may include an inlet portion 144 into which another portion of an airflow generated from the cooling fan 113 is introduced, an outlet portion 145 through which the introduced airflow is discharged, and a first flow path 146 provided to allow the inlet portion 144 and the outlet portion 145 to communicate with each other. The branch guide 180 may include an extension portion 181 extending along the first flow path 146, and a curved portion 183 curved from one end of the extension portion 181 adjacent to the outlet portion 145 toward an inside of the user interface 160 so as to be positioned above the outlet portion 145.

The heat absorption portion 141 may include a heat absorption block 141 extending along a longitudinal direction of the firs flow path 146. The heat dissipation portion may include a plurality of heat dissipation fins 142 protruding from a lateral portion of the heat absorption block 141, arranged in an up and down direction, and provided to come into contact with the airflow generated by the cooling fan 131. The extension portion 181 and the curved portion 183 may form second flow paths 182 and 184 partitioned from the first flow path 146, and may be disposed at a height corresponding to a height at which a first heat dissipation fin 142a, which is located at an uppermost position among the plurality of heat dissipation fins 142, is disposed.

The heat dissipation member 140 may include a spare space 143 formed in such a way that the first heat dissipation fin 142a protrudes shorter from the heat absorption block 141 than the remaining heat dissipation fins excluding the first heat dissipation fin 142a. The branch guide 180 may be disposed in the spare space 143.

The induction heating cooking device 1 may further include a cover duct 150 provided to cover the heat dissipation member 140 to guide another portion of the airflow generated from the cooling fan 113 to the heat dissipation member 140. The cover duct 150 and the branch guide 180 may be arranged to be in contact with each other.

An induction heating cooking device 1 according to one embodiment may include a plate 10 for placing a cooking container thereon, a heating device 170 configured to heat the cooking container by receiving a driving current from a printed circuit board 120, a user interface 160 for receiving a user input for operating the heating device 170, a heat dissipation member 140 disposed below the user interface 160 and configured to absorb and release heat generated from the printed circuit board 120 and including an inlet portion 144 into which an airflow receiving heat released from the printed circuit board 120 is introduced, and an outlet portion 145 into which the airflow is discharged, and a cooling fan 113 configured to generate an airflow for cooling the user interface 160 and the heat dissipation member 140. The induction heating cooking device 1 may include a first duct 150 provided to cover the heat dissipation member 140 to guide a portion of the airflow generated by the cooling fan 113 to the heat dissipation member 140, and a second duct 180 provided to guide another portion of the airflow generated by the cooling fan 113 to the user interface 160, disposed between the outlet portion 145 and the user interface 160, and partitioned from the first duct 150.

While the present disclosure has been particularly described with reference to exemplary embodiments, it should be understood by those of skilled in the art that various changes in form and details may be made without departing from the spirit and scope of the present disclosure.

1. An induction heating cooking device comprising:
a plate to allow a cooking container to be placed thereon;
a heating device configured to heat the cooking container by receiving a driving current from a printed circuit board; and
a user interface to receive a user input for operating the heating device;
a heat dissipation member, to be disposed below the user interface, configured to exchange heat with the printed circuit board;
a cooling fan configured to generate an airflow to cool the heat dissipation member; and
a branch guide, including a first flow path and a second flow path, to guide a portion of the airflow generated by the cooling fan to the user interface, wherein the second flow path is disposed above and separated from the first flow path such that air to cool the heat dissipation member flows through the first flow path.

2. The induction heating cooking device of claim 1, wherein
the heat dissipation member comprises:
a heat absorption block provided to absorb heat from the printed circuit board; and
a plurality of heat dissipation fins protruding from a lateral portion of the heat absorption block and arranged along an up and down direction, provided to release heat absorbed by the heat absorption block and provided to come into contact with the airflow generated by the cooling fan,
wherein the second flow path is disposed at a height corresponding to a height at which a first heat dissipation fin, which is located at an uppermost position among the plurality of heat dissipation fins, is disposed.

3. The induction heating cooking device of claim 2, wherein
the plurality of heat dissipation fins comprises:
an inlet portion into which an airflow generated from the cooling fan is introduced, the inlet portion formed in such a way that each end of the plurality of heat dissipation fins adjacent to the cooling fan is spaced apart from each other; and
an outlet portion through which the introduced airflow is discharged, the outlet portion formed in such a way that the other end of the plurality of heat dissipation fins is spaced apart from each other,
wherein the first flow path is formed to allow the inlet portion and the outlet portion to communicate with each other.

4. The induction heating cooking device of claim 3, wherein
the branch guide comprises:
an extension portion extending along a longitudinal direction of the first heat dissipation fin; and
a curved portion formed to surround the first heat dissipation fin and the heat absorption block, positioned above the outlet portion to allow the outlet portion to be exposed, and curved from the extension portion toward an inside of the user interface.

5. The induction heating cooking device of claim 3, wherein
the heat dissipation member comprises a spare space formed in such a way that the first heat dissipation fin protrudes shorter from the heat absorption block than remaining heat dissipation fins excluding the first heat dissipation fin,
wherein the branch guide is disposed in the spare space.

6. The induction heating cooking device of claim 5, wherein
the branch guide is spaced apart from the plurality of heat dissipation fins and the branch guide is disposed in the spare space.

7. The induction heating cooking device of claim 3, further comprising:
a case covered by the plate and provided to accommodate the cooling fan, the branch guide, and the user interface,
wherein the user interface comprises an outlet through which an airflow introduced into an inside of the user interface is discharged,
wherein the case comprises a case hole provided to allow the outlet to communicate with an outside so as to discharge an airflow discharged from the user interface to the outside.

8. The induction heating cooking device of claim 7, wherein
the case hole is formed to allow the outlet portion of the heat dissipation member to communicate with the outside.

9. The induction heating cooking device of claim 2, wherein
the branch guide comprises an insulating material.

10. The induction heating cooking device of claim 5, further comprising:
a cover duct provided to cover the heat dissipation member to guide another portion of the airflow generated from the cooling fan to the heat dissipation member,
wherein the cover duct and the branch guide are arranged to be in contact with each other.

11. The induction heating cooking device of claim 10, wherein
the cover duct comprises a cutout portion formed to communicate with the spare space,
wherein the branch guide is inserted into the cutout portion and disposed in the spare space.

12. The induction heating cooking device of claim 11, wherein
the cover duct and the branch guide are integrally formed.

13. The induction heating cooking device of claim 1, further comprising:
a cover duct provided to cover the heat dissipation member to guide another portion of the airflow generated from the cooling fan to the heat dissipation member,
wherein the branch guide is arranged to be placed on an upper surface of the cover duct.

14. The induction heating cooking device of claim 10, further comprising:
a case covered by the plate and provided to accommodate the cooling fan, the branch guide, and the user interface,
wherein the cover duct further comprises a lead portion provided to guide the airflow discharged from the outlet portion to a lower surface of the case,
wherein the case comprises a case hole provided to allow the lead portion to communicate with an outside to discharge an airflow discharged from the outlet portion to the outside.

15. The induction heating cooking device of claim 10, wherein
the branch guide comprises an insulating material.
